(19) United States
(12) Patent Application Publication
(10) Pub. No.: US 2007/0085561 A1
(43) Pub. Date: Apr. 19, 2007

(54) OUTPUT CIRCUIT FOR A HUB CHIP FOR OUTPUTTING A HIGH-FREQUENCY SIGNAL, A HUB CHIP, A MEMORY MODULE AND A METHOD FOR OPERATING AN OUTPUT CIRCUIT

(76) Inventor: Dirk Friebe, Munich, DE (US)

Correspondence Address: PATTERSON & SHERIDAN, LLP;Gero McClellan / Infineon / Qimonda, 3040 POST OAK BLVD.,, SUITE 1500, HOUSTON, TX, 77056, US

(21) Appl. No.: 11/535,834

(22) Filed: Sep. 27, 2006

(30) Foreign Application Priority Data
Sep. 27, 2005 (DE) 102005046192.1-53

(51) Int. Cl. H03K 19/003

(52) U.S. Cl. 326/30

(57) ABSTRACT

The invention relates to an output circuit for a hub chip and a method for actuating an output circuit for outputting a high-frequency differential output signal between a first and a second output node, having a differential amplifier unit which comprises a first switching device and a first terminating resistor which are connected in series between a high supply potential and a low supply potential and between which the first output node is provided, and a second switching device and a second terminating resistor which are connected in series between the high supply potential and the low supply potential and between which the second output node is provided. A control unit opens one of the first and second switching devices and closes the respective other one when there is a level change to be made in the output signal, such that the switching device which is to be opened is switched at a time before the other switching device, which is to be closed.

### CROSS-REFERENCE TO RELATED APPLICATIONS

This application claims foreign priority benefits under 35 U.S.C. §119 to co-pending German patent application number DE 10 2005 046 192.1-53, filed 27Sep. 2005. This related patent application is herein incorporated by reference in its entirety.

### BACKGROUND OF THE INVENTION

1. Field of the Invention

The invention relates to an output circuit for a hub chip outputting a high-frequency signal. The invention also relates to a method for actuating a hub chip of this kind which is intended to be used to output a high-frequency signal.

2. Description of the Related Art

Currently, some advanced memory modules have a hub chip which receives high-frequency external signals containing serialized data, converts them to parallel and forwards them to memory chips in the memory module if one or more of the memory chips has been addressed. If none of the memory chips have been addressed, the hub chip serializes the received data in order to transmit them to a hub chip for a downstream memory module, for example. Such memory modules are also called fully buffered DIMMs (FB-DIMMs). This allows faster memory access speeds and increases the total storage capacity per module over conventional memory modules. Such fully buffered DIMMs are connected in succession in the form of a daisy chain, so that between the memory modules there is just one point-to-point signal connection between the hub chips of the respective memory module, which are also called advanced memory buffers (AMBs).

To ensure safe signal transmission even at high data transmission rates, such as between 3.2 Gbit/s and 4.8 Gbit/s, certain requirements prescribed by the specification need to be met for signal output from the hub chip. By way of example, two data streams, each having a signal swing of 0 to V_{DD}, in a transmitter of the hub chip need to be serialized and converted to produce a differential data signal which has a normally small signal level swing differing from the original signal swing. In addition, the outputs need to be referenced to ground potential via a 50Ω termination. Another requirement is that the mid-level potential between the two output nodes is as constant as possible and that when the output nodes are switched from one signal state to another there is no significant difference from the mid-level potential between the high signal level and the low signal level of the output signal. This is necessary for correct reception of the high-frequency signals at the receiver end.

While the hub chip is normally implemented using CMOS logic in order to reduce power consumption, the output driver is implemented using what is known as common mode logic (CML) circuitry in order to achieve the high signal transmission rates. Particularly when using NMOS field-effect transistors, very high speeds can be achieved in this context. When using NMOS field-effect transistors, it is a simple matter to achieve termination for the high supply potential V_{DD}, but not for the ground potential, as required in the specification for the hub chip. In the case of termination for the ground potential, as provided in the case of the hub chip for fully buffered DIMMs, pure CML implementation is possible only with PMOS transistors, however. Since PMOS transistors normally switch somewhat slower than NMOS transistors given the same dimensions, this means that it is no longer possible to achieve a demanded data transmission rate of 4.8 Gbit/s. This can be approximately compensated for by suitable measures, e.g. larger proportioning of the PMOS transistors, by the provision of passive or active coils, but this requires increased surface area for implementing an output driver of this kind in the integrated circuit of the hub chip.

The output circuit of such a hub chip is usually designed using a plurality of stages in which the CMOS output signal needs to be converted into a CML signal. A drawback of designing the output circuit using common mode logic when there are a plurality of stages is the high power consumption of CML logic. Regardless of the input signal, a static current flows, the static current being determined by the amplitude and the terminating resistor at the output of the output circuit.

### SUMMARY OF THE INVENTION

According to an aspect, the invention refers to a hub chip with an output circuit. According to a further aspect, the invention refers to a memory module comprising a hub chip with an output circuit.

According to one aspect, the invention refers to an output circuit for a hub chip for outputting a high-frequency differential output signal between a first and a second output node, having a differential amplifier unit which comprises: a first switching device and a first terminating resistor which are connected in series between a high supply potential and a low supply potential and between which the first output node is provided, a second switching device and a second terminating resistor which are connected in series between the high supply potential and the low supply potential and between which the second output node is provided, the first terminating resistor and the second terminating resistor being provided in order to terminate the first and second output nodes for one of the supply potentials; and having a control unit which opens one of the first and second switching devices when there is a level change to be made in the output signal and closes the respective other one and actuates the switching devices such that the switching device which is to be opened is switched at a time before the other switching device, which is to be closed.

According to a further aspect, the invention refers to a hub chip with an output circuit for outputting a high-frequency differential output signal between a first and a second output node, having a differential amplifier unit which comprises: a first switching device and a first terminating resistor which are connected in series between a high supply potential and a low supply potential and between which the first output node is provided, a second switching device and a second terminating resistor which are connected in series between the high supply potential and the low supply potential and between which the second output node is provided, the first terminating resistor and the second terminating resistor being provided in order to terminate the first and second output nodes for one of the supply potentials; and having a control unit which opens one of the first and second switching devices when there is a level change to be made in the output signal and closes the respective other one and actuates the switching devices such that the switching device which is to be opened is switched at a time before the other switching device, which is to be closed.

According to a further aspect, the invention refers to a memory module comprising a hub chip with an output circuit for outputting a high-frequency differential output signal between a first and a second output node, having a differential amplifier unit which comprises: a first switching device and a first terminating resistor which are connected in series between a high supply potential and a low supply potential and between which the first output node is provided, a second switching device and a second terminating resistor which are connected in series between the high supply potential and the low supply potential and between which the second output node is provided, the first terminating resistor and the second terminating resistor being provided in order to terminate the first and second output nodes for one of the supply potentials; and having a control unit which opens one of the first and second switching devices when there is a level change to be made in the output signal and closes the respective other one and actuates the switching devices such that the switching device which is to be opened is switched at a time before the other switching device, which is to be closed.

According to another aspect, the invention refers to a method for actuating an output circuit for a hub chip for outputting a high-frequency differential output signal between a first output node and a second output node, the output circuit comprising: a first switching device and a first terminating resistor which are connected in series between a high supply potential and a low supply potential and between which the first output node, and a second switching device and a second terminating resistor which are connected in series between the high supply potential and the low supply potential and between which the second output node, one of the first and second switching devices being opened when there is a level change to be made in the output signal and the respective other one being closed and actuated such that the switching device which is to be opened is switched at a time before the switching device which is to be closed.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows a block diagram of an output circuit for a hub chip in a fully buffered DIMM memory module based on the prior art;

FIG. 2 shows a circuit diagram for an output circuit in a hub chip based on the prior art;

FIG. 3 shows a circuit diagram for an output circuit based on a preferred embodiment of the invention; and

FIG. 4 shows signal/time graphs for the actuation signals for the input drivers in the embodiment of the inventive output circuit shown in FIG. 3.

### DETAILED DESCRIPTION OF THE PREFERRED EMBODIMENT

Advanced fully buffered DIMM memory modules have, besides memory chips, what is known as a hub chip which the memory chips use to communicate with a memory controller. The hub chip is connected to the memory controller by a point-to-point connection which allows data to be transmitted at very high speeds. The hub chip is provided such that the data transmission from and to the memory controller is performed essentially serially. Received data are then converted to parallel in the hub chip and are made available to one of the memory chips when it is addressed. Data to be sent are first of all serialized by the hub chip and are sent either to the memory controller or to another hub chip in a subsequent fully buffered DIMM memory module via an output circuit serially at a high transmission rate of up to 4.8 Gbit/sec using another point-to-point connection. When there are a plurality of fully buffered DIMM memory modules, these are typically connected to one another in the form of a daisy chain, i.e. data are not transmitted directly from the memory controller to each of the fully buffered DIMM memory modules (in star form), but rather are first of all sent to a first memory module and from there to a second memory module or received from a second memory module via the first memory module in the memory controller via separate outward and return lines.

To be able to provide the high transmission rates, the output circuits in such a hub chip need to be of suitable design. In particular, the output circuits need to provide an output signal which meets certain specifications (e.g., one to be provided by the JEDEC) for fully buffered DIMM memory modules. Already known, demands on the output circuit in a hub chip of this kind involve a data transmission rate of at least 4.8 Gbit/sec needing to be achieved. The output signal is intended to be provided as a differential output signal which is terminated for the ground potential and which has a predetermined signal swing, differing from the supply voltage of 250 to 450 mV single ended (at one output node). In addition, the aim is for the mid-level voltage of the differential output signal to remain as constant as possible even during the level change in order to ensure safe operation of the input circuit to which the differential output signal is applied at the receiver end.

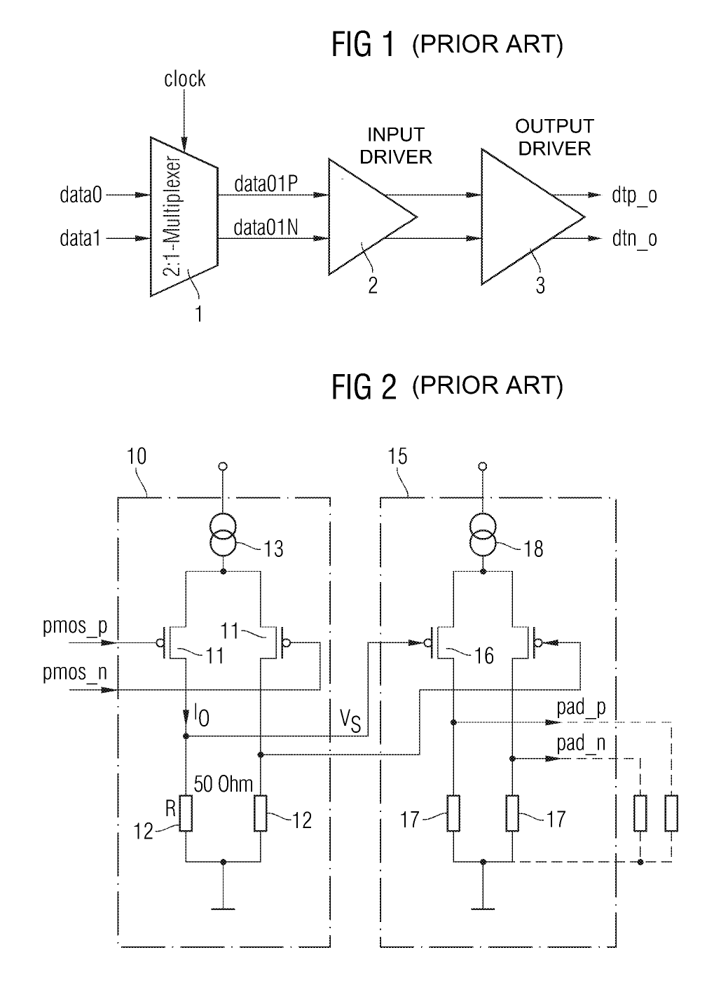

The parallel data which are present in the hub chip are serialized in a plurality of stages, with two data signals data0, data1 which have already been serialized in part, for example, being supplied to an output circuit. A block diagram of an output circuit based on the prior art is shown in FIG. 1. The partially serialized data data0, data1 are supplied to a 2:1 multiplexer 1 which serializes the data and supplies them to an input driver circuit 2 as a differential output signal data01P, data01N. The input driver circuit 2 generates actuation signals for appropriate switching devices in an output driver 3 in order to produce the differential output signal DTP, DTN.

FIG. 2 shows an example of an input driver and an output driver from FIG. 1 as a circuit diagram in detail. The output circuit in FIG. 2 comprises an input driver 10 which is in the form of a differential amplifier circuit and receives a differential input signal PMOS_P, PMOS_N. The differential amplifier circuit has two current paths respectively containing a PMOS transistor 11 and a terminating resistor 12 connected in series therewith, the respective output node for outputting a differential control signal Vₛ being arranged between the PMOS transistor 11 and the terminating resistor 12. The differential control signal Vₛhas a signal swing which matches the specification and which can be set by a current source 13. The signal to be output is applied in differential form to appropriate control inputs of the PMOS transistors 11. The differential control signal Vₛ which is output by the input driver 10 is supplied to an output driver 15 which has a further differential amplifier which is of the same type of design as the differential amplifier in the input driver 10. The output nodes of the input driver 10 are connected to the control connections of the PMOS transistors in the further differential amplifier of the output driver 15. Each current path in the further differential amplifier contains a PMOS transistor 16 and a terminating resistor 17 which are connected in series and between which the respective output node for outputting the output signal is provided. The respective terminating resistor 17 has one connection connected to the ground potential and thus forms a new termination for the ground potential. A further current source 18 is provided which can be used to set the signal swing in the output signal in accordance with the specification.

Such an output circuit has the drawback that when using PMOS transistors it is only possible to achieve a lower data transmission frequency than when using NMOS transistors for a prescribed surface area. Although it would be possible to use NMOS transistors to design an output circuit of this kind this would only be so if the output nodes were terminated for the high supply potential. This is not admissible according to specification, however.

A first aspect of the present invention is to provide an output circuit for outputting a high-frequency differential signal which satisfies the prescribed specifications and which also has a reduced power consumption over the prior art.

A further aspect of the present invention is to provide a method for operating an output circuit which meets the prescribed specifications.

In line with the first aspect of the present invention, an output circuit for a hub chip for outputting a high-frequency differential output signal between a first and a second output node is provided. The output circuit has a differential amplifier unit which has a first switching device and a first terminating resistor, which are connected in series between a high supply potential and a low supply potential and between which the first output node is provided, and also a second switching device and a second terminating resistor, which are connected in series between the high supply potential and the low supply potential and between which the second output node is provided. The first terminating resistor and the second terminating resistor are provided in order to terminate the first and second output nodes for one of the supply potentials. In addition, the output circuit comprises a control unit which opens one of the first and second switching devices when there is a level change to be made in the output signal and closes the respective other one and actuates it such that the switching device which is to be closed is switched at a time after the switching device which is to be opened.

One embodiment of the output circuit has the advantage that a state in which both switching devices are closed is essentially avoided. When transmitting high-frequency differential output signals, it is desirable, particularly when transmitting signals between hub chips for fully buffered DIMM memory modules, for the mid-level potential (common mode potential) to remain as constant as possible, but at any rate, a dip in the mid-level potential to the low supply potential needs to be avoided. The fact that the successive switching avoids a brief switching state in which both switching devices are closed therefore prevents the first and second terminating resistors from altering the mid-level potential in the direction of one of the supply potentials for which the terminating resistors are terminated.

The first terminating resistor may terminate the first output node and the second terminating resistor may terminate the second output node for the low supply potential, particularly for a ground potential. This makes it possible to provide an output circuit which meets the specifications for an output circuit for a fully buffered DIMM memory module.

In line with another embodiment, the control unit can actuate the switching devices such that the closure of the switching device which is to be closed is delayed over the opening of the switching device which is to be opened. This is a simple way of switching the switching devices in offset fashion.

In addition, the high and low supply potentials can be provided by providing a settable current source whose current level is set on the basis of a desired level swing in the output signal. This allows the output signal's level swing prescribed by the specification to be set.

In line with a further embodiment, at least one of the first and second switching devices can be produced using two parallel-connected transistors of complementary conductivity type. In particular, the control unit can generate actuation signals which are applied to control inputs of the complementary transistors, the actuation signals for the switching device which is to be closed upon a signal change having a reduced edge gradient over the edge gradient of the actuation signals for the switching device which is to be opened. The reduced edge gradient prompts the switching time for the transistors to be reached later in comparison with a switching time for an unreduced edge gradient. In this way, a delay in the switching time can thereby be achieved in simple fashion.

For generating the actuation signals, the control unit may have an input driver unit with a plurality of input drivers, each input driver providing an actuation signal having a respective greater edge gradient in a first edge direction and a lesser edge gradient in a second edge direction, with at least one of the switching devices, which has two transistors of complementary conductivity type, being connected to two input drivers such that when the switching device is closed both transistors are actuated upon that edge of the relevant actuation signal which has the lesser edge gradient.

Another aspect of the present invention refers to a method for actuating an output circuit for a hub chip for outputting a high-frequency differential output signal between a first output node and a second output node. In this context, the output circuit has a first switching device and a first terminating resistor which are connected in series between a high supply potential and a low supply potential and between which the first output node is provided, and also a second switching device and a second terminating resistor which are connected in series between the high supply potential and the low supply potential and between which the second output node is provided. In line with one embodiment of the invention, one of the first and second switching devices is opened when there is a level change to be made in the output signal and the respective other one is closed and actuated such that the switching device which is to be opened is switched at a time before the switching device which is to be closed. The method has the advantage that an output circuit for operating a high-frequency output signal, particularly for a hub chip in a fully buffered DIMM memory module, can be operated such that a mid-level potential for the output signal does not change in the direction of the supply potential for which the terminating resistors are terminated during the switching phase.

The switching devices may be actuated such that when a change is to be made in the level of the output signal the closure of the switching device which is to be closed is delayed over the opening of the switching device which is to be opened.

In a further embodiment, at least one of the first and second switching devices can be produced using two parallel-connected transistors of complementary conductivity type, with actuation signals being applied to control inputs of the complementary transistors, so that the actuation signals for the transistors in the switching device which is to be closed upon a signal change have a reduced edge gradient over the edge gradient of the actuation signals for the corresponding other switching device.

An actuation signal respectively having a greater edge gradient in a first edge direction and a lesser edge gradient in a second edge direction can be provided for each of the control inputs of the transistors in the first and second switching devices, the change in the level of the output signal when the relevant switching device is closed prompting both transistors to be actuated by the respective actuation signal with the lesser edge gradient.

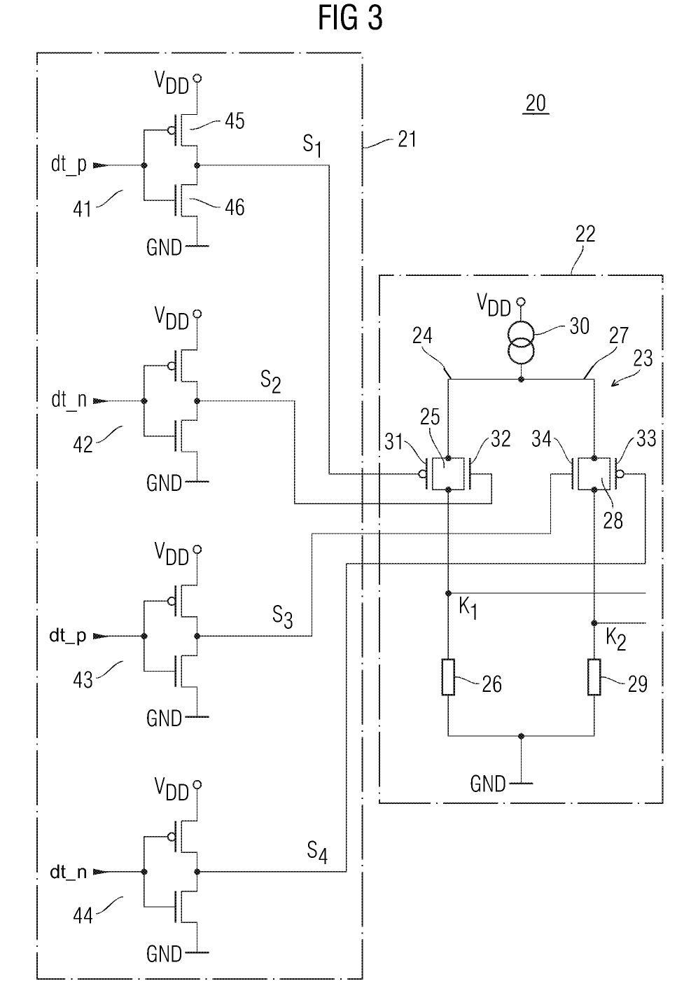

FIG. 3 depicts an output circuit 20. The output circuit 20 comprises an input driver circuit 21 and an output stage 22 which comprises a differential amplifier circuit 23. The differential amplifier circuit 23 has a first current path 24 and a second current path 27. The first current path comprises a first switching device 25 and a resistor 26 which are connected in series between a high supply potential V_{DD} and a low supply potential GND. The second current path 27 comprises a second switching device 28 and a second resistor 29, which are likewise connected in series between the high supply potential V_{DD} and the ground potential GND. Between the respective switching device 25, 28 and the relevant resistor 26, 29 there are output nodes K₁, K₂ at which the differential output signal is output. The resistors 26, 29 are arranged between the respective output nodes K₁, K₂ and the ground potential.

A current source 30 is provided which can be used to set the current through the differential amplifier circuit 23. The resistors 26, 29 are provided as terminating resistors for the data transmission line which is applied to the output nodes K₁, K₂. In one embodiment, the resistors 26, 29 have a resistance value of 50Ω each.

The switching devices 25, 28 are respectively designed with two parallel-connected transistors, the first switching device 25 with a first p-channel field-effect transistor 31 and a first n-channel field-effect transistor 32 and the second device 28 with a second p-channel field-effect transistor 33 and a second n-channel field-effect transistor 34. Each of the p-channel field-effect transistors 31, 33 and each of the n-channel field-effect transistors 32, 34 are actuated by a separate actuation signal S₁ to S₄.

The actuation signals S₁ to S₄ are provided by the input driver circuit 21, each of the actuation signals S₁ to S₄, being provided by a separate input driver 41, 42, 43, 44. The actuation signals S₁ to S₄ are chosen so that when there is an imminent level change in the output signal the switching devices 25, 28 are switched in opposite fashion to one another. This means that the respective open switching device is closed and the respective closed switching device is opened. To prevent the mid-level voltage of the output signal which is output at the two output nodes K₁ and K₂ from dipping toward the ground potential during the switching phase, the actuation signals S₁ to S₄ are provided such that the switching device which is to be closed is closed after a delay, so that the state in which both switching devices are closed is avoided.

In addition, the NMOS transistor connected in parallel with the PMOS transistor is used to compensate for the PMOS transistor as a band-limiting factor of the output stage. The result is a differential P/NMOS switch in the output stage. This design of the switching device achieves an extension to the bandwidth, i.e. an increase in the driver power, and a simple implementation of a signal level conversion in one step.

The first p-channel field-effect transistor 31 and the first n-channel field-effect transistor 32 are essentially actuated with mutually inverse signal levels of the actuation signals S₁ and S₂. The second p-channel field-effect transistor 33 and the second n-channel field-effect transistor 34 are accordingly actuated using mutually inverse signal levels S₃ and S₄. To ensure that both switching devices are not closed at any time, the switching of the switching device which is to be closed is delayed by reducing the edge gradient of the relevant edge of the actuation signals, so that the switching threshold of the respective p-channel field-effect transistor and n-channel field-effective transistor is reached later than would be the case for an edge with an unreduced edge gradient.

The input drivers 41 to 44 are respectively designed as an inverter circuit in which a further p-channel field-effect transistor 45 and a further n-channel field-effect transistor 46 are respectively connected in series with one another. The control inputs of the further p-channel field-effect transistor 45 and of the further n-channel field-effect transistor 46 have one of two signal portions dt_p, dt_n of the differential output signal which is to be output applied to them. The inputs of the first and third input drivers have the signal portion dt_p applied to them and the inputs of the second and fourth input drivers have the signal portion dt_n applied to them.

The different edge gradient of the rising and falling edges can be set by the channel width of the further p-channel field-effect transistor 45 or n-channel field-effect 46 in each of the input drivers, for example. If the rising edge of the actuation signal is intended to have its edge gradient reduced then the driver capability, i.e. the channel width of the p-channel field-effect transistor 45, needs to be appropriately reduced over the driver power of the n-channel field-effect transistor 46 or its channel width. In this context, it is necessary to take into account of the fact that the driver capabilities of p-channel and n-channel field-effect transistors are different, i.e. the driver capability of an n-channel field-effect transistor is approximately three times as great as the driver capability of a corresponding p-channel field-effect transistor for the same channel width.

As regards the proportioning of the input drivers 41, 42, 43, 44, a respective one of the field-effect transistors needs to be provided with a first driver capability and the respective other field-effect transistor needs to be provided with a second driver capability, which is reduced in comparison therewith, which means that one of the edges of the relevant actuation signal S₁ to S₄ has a reduced edge gradient over the respective other edge. In one embodiment, the input drivers 41 and 44 have identical proportions, and the input drivers 42 and 43 have identical proportions.

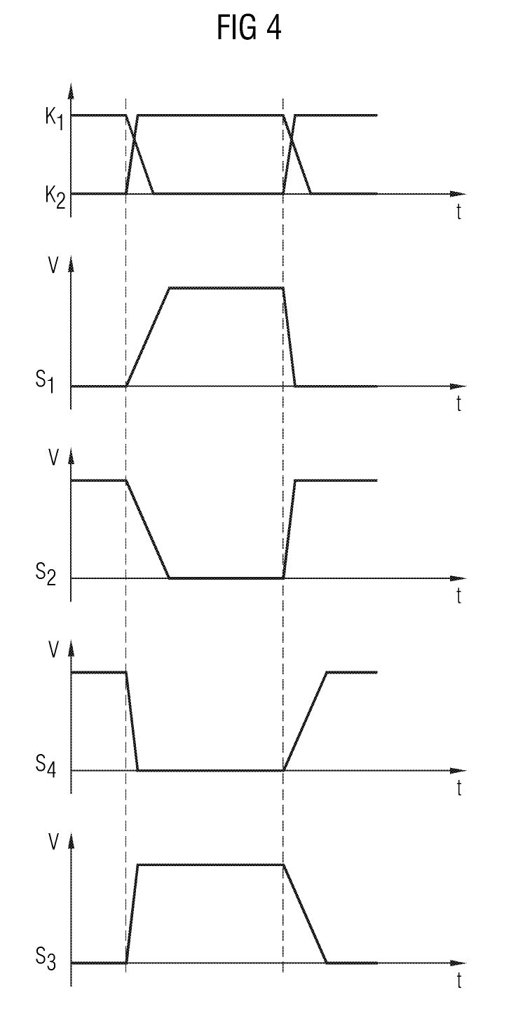

FIG. 4 shows a signal/time graph for the actuation signals for the exemplary embodiment in FIG. 3 in schematic form. The profiles of the edges correspond to an exponential function with a high gradient magnitude at the start and a reduced gradient magnitude toward the end of the duration of the edge. It can be seen that the rising edge of the actuation signal S₁ and the falling edge of the actuation signal S₂ have a reduced edge gradient so that these edges are intended to be used to switch the first p-channel field-effect transistor 31 and the first n-channel field-effect transistor 32 from the open state to the closed state. This switching is intended to be delayed in comparison with the second switching device opening. For this reason, the rising edge of the third actuation signal S₃ and the falling edge of the fourth actuation signal S₄ do not have a reduced edge gradient, which means that the second switching device 28 changes as quickly as possible to the open state.

In the converse case, in which the second node K₂ is intended to have a low output potential applied to it and the first node K₁ is intended to have a high output potential applied to it, this is achieved by a falling edge of the first actuation signal S₁ and a rising edge of the second actuation signal S₂ with respectively unreduced edge gradient, while the falling edge of the third actuation signal S₃ and the rising edge of the fourth actuation signal S₄ have a reduced edge gradient.

The use of a p-channel field-effect transistor and of an n-channel field-effect transistor to implement one of the switching devices means that these can be actuated using the conventional CMOS voltage levels, namely a high supply potential and a low supply potential, without these needing to be brought to the appropriate CML voltage levels which need to be provided for the output signal which is to be output.

In the case of the proposed output circuit, the relevant voltage levels of the output signal can be set by setting the current source 30, the levels of the actuation signals for the first and second n-channel and p-channel field-effect transistors 31, 32, 33, 34 being uncritical.

While the foregoing is directed to embodiments of the present invention, other and further embodiments of the invention may be devised without departing from the basic scope thereof, and the scope thereof is determined by the claims that follow.

What is claimed is:

1. An output circuit for a hub chip for outputting a high-frequency differential output signal between a first and a second output node, comprising:
a differential amplifier unit which comprises:
a first switching device and a first terminating resistor which are connected in series between a high supply potential and a low supply potential, wherein the first output node is provided between the first switching device and the first terminating resistor; and
a second switching device and a second terminating resistor which are connected in series between the high supply potential and the low supply potential, wherein the second output node is provided between the second switching device and the second terminating resistor, the first terminating resistor and the second terminating resistor provided to terminate the first and second output nodes for one of the supply potentials; and
a control unit which opens one of the first and second switching devices when a level change is to be made in the output signal and closes the respective other one of the first and second switching devices, wherein the switching device which is to be opened is switched at a time before the other switching device which is to be closed.

2. The output circuit of claim 1, wherein the first terminating resistor terminates the first output node and the second terminating resistor terminates the second output node for the low supply potential.

3. The output circuit of claim 1, wherein the control unit actuates the switching devices such that a closure of the switching device which is to be closed is delayed.

4. The output circuit of claim 2, wherein the control unit actuates the switching devices such that a closure of the switching device which is to be closed is delayed.

5. The output circuit of claim 1, further comprising a settable current source which is set based on a desired level swing in the output signal, wherein the high and low supply potentials are provided by the settable current source.

6. The output circuit of claim 1, wherein at least one of the first and second switching devices comprises two parallel-connected transistors of complementary conductivity type.

7. The output circuit of claim 6, wherein the control unit generates actuation signals which are applied to control inputs of the complementary transistors, the actuation signals for the switching device which is to be closed upon a signal change having a reduced edge gradient compared to an edge gradient of the actuation signals for the switching device which is to be opened.

8. The output circuit of claim 7, wherein the control unit comprises an input driver unit having a plurality of input drivers for generating each of the actuation signals, each input driver providing a respective actuation signal having a respective greater edge gradient in a first edge direction and a lesser edge gradient in a second edge direction, wherein at least one of the switching devices is connected to two input drivers such that when the switching device is closed both transistors are actuated upon the respective edge of the relevant actuation signal which has the lesser edge gradient.

9. A hub chip comprising an output circuit for outputting a high-frequency differential output signal between a first and a second output node, the output circuit comprising:
a differential amplifier unit which comprises:
a first switching device and a first terminating resistor which are connected in series between a high supply potential and a low supply potential, wherein the first output node is provided between the first switching device and the first terminating resistor; and
a second switching device and a second terminating resistor which are connected in series between the high supply potential and the low supply potential, wherein the second output node is provided between the second switching device and the second terminating resistor, the first terminating resistor and the second terminating resistor provided to terminate the first and second output nodes for one of the supply potentials; and
a control unit which opens one of the first and second switching devices when a level change is to be made in the output signal and closes the respective other one of the first and second switching devices, wherein the switching device which is to be opened is switched at a time before the other switching device which is to be closed.

10. The hub chip of claim 9, wherein the first terminating resistor terminates the first output node and the second terminating resistor terminates the second output node for the low supply potential.

11. The hub chip of claim 9, wherein the control unit actuates the switching devices such that a closure of the switching device which is to be closed is delayed.

12. A memory module comprising a hub chip with an output circuit for outputting a high-frequency differential output signal between a first and a second output node, the output circuit comprising:
a differential amplifier unit which comprises:
a first switching device and a first terminating resistor which are connected in series between a high supply potential and a low supply potential, wherein the first output node is provided between the first switching device and the first terminating resistor; and
a second switching device and a second terminating resistor which are connected in series between the high supply potential and the low supply potential, wherein the second output node is provided between the second switching device and the second terminating resistor, the first terminating resistor and the second terminating resistor provided to terminate the first and second output nodes for one of the supply potentials; and
a control unit which opens one of the first and second switching devices when a level change is to be made in the output signal and closes the respective other one of the first and second switching devices, wherein the switching device which is to be opened is switched at a time before the other switching device which is to be closed.

13. The memory module of claim 12, wherein the first terminating resistor terminates the first output node and the second terminating resistor terminates the second output node for the low supply potential.

14. The memory module of claim 12, wherein the control unit actuates the switching devices such that a closure of the switching device which is to be closed is delayed.

15. A method for actuating an output circuit for a hub chip for outputting a high-frequency differential output signal between a first output node and a second output node, the output circuit comprising a differential amplifier unit which comprises a first switching device and a first terminating resistor which are connected in series between a high supply potential and a low supply potential, wherein the first output node is provided between the first switching device and the first terminating resistor, and a second switching device and a second terminating resistor which are connected in series between the high supply potential and the low supply potential, wherein the second output node is provided between the second switching device and the second terminating resistor, the method comprising:
when a level change is to be made in the output signal, opening one of the first and second switching devices and closing the respective other one of the first and second switching devices, wherein the switching device which is to be opened is switched at a time before the other switching device which is to be closed.

16. The method of claim 15, wherein the switching devices are actuated such that a closure of the switching device which is to be closed is delayed until after an opening of the switching device which is to be opened.

17. The method of claim 15, wherein at least one of the first and second switching devices comprises two parallel-connected transistors of complementary conductivity type, wherein actuation signals are applied to control inputs of the complementary transistors, wherein the actuation signals for the transistors in the switching device which is to be closed upon the signal change have a reduced edge gradient compared to the edge gradient of the actuation signals for the other switching device.

18. The method of claim 16, wherein at least one of the first and second switching devices comprises two parallel-connected transistors of complementary conductivity type, wherein actuation signals are applied to control inputs of the complementary transistors, wherein the actuation signals for the transistors in the switching device which is to be closed upon the signal change have a reduced edge gradient compared to the edge gradient of the actuation signals for the other switching device.

19. The method of claim 17, wherein a respective actuation signal having a greater edge gradient in a first edge direction and a lesser edge gradient in a second edge direction is provided respectively for each of the control inputs of the transistors in the first and second switching devices, and wherein, for the relevant switching device being closed, both transistors are actuated by the respective actuation signal with the lesser edge gradient.

20. The method of claim 18, wherein a respective actuation signal having a greater edge gradient in a first edge direction and a lesser edge gradient in a second edge direction is provided respectively for each of the control inputs of the transistors in the first and second switching devices, and wherein, for the relevant switching device being closed, both transistors are actuated by the respective actuation signal with the lesser edge gradient.
